(19) United States
(12) Patent Application Publication
(10) Pub. No.: US 2024/0036198 A1
(43) Pub. Date: Feb. 1, 2024

(54) Optical Ranging Device

(71) Applicant: Egis Technology Inc., Hsinchu City (TW)

(72) Inventors: Wan-Jung Lo, Hsinchu City (TW); Chen-Chih Fan, Hsinchu City (TW)

(21) Appl. No.: 18/089,070

(22) Filed: Dec. 27, 2022

Related U.S. Application Data
(60) Provisional application No. 63/401,101, filed on Aug. 25, 2022.
(60) Provisional application No. 63/392,495, filed on Jul. 27, 2022.

(30) Foreign Application Priority Data
Dec. 15, 2022 (CN) 202211613595.9

(51) Int. Cl. G01S 17/10; G01S 7/4863; G01S 7/4865; H01L 31/107

(52) U.S. Cl. CPC G01S 17/10; G01S 7/4863; G01S 7/4865; H01L 31/107

(57) ABSTRACT

Embodiments of the present disclosure provide an optical ranging device capable of reducing or eliminating pile up effect in DToF ranging method. The optical ranging device comprises a light source; a sensor module comprising a SPAD array, wherein the SPAD array comprises a first SPAD group without aperture and a second SPAD group with a first aperture, and the sensor module separately outputs a photon detection value corresponding to a number of photons received by each SPAD group; and a processing module for calculating a distance between the object to be measured and the ranging device using the photon detection value based on DToF. In response to light intensity received by the SPAD array in a first pulse window being greater than a first threshold, the distance is calculated using the photon detection value of the second SPAD group in the first pulse window.

### CROSS REFERENCE TO RELATED APPLICATIONS

This application claims priority to U.S. Provisional Application No. 63/392,495 filed on Jul. 27, 2022, and to U.S. Provisional Application No. 63/401,101 filed on Aug. 25, 2022, and to Chinese Patent Application No. 202211613595.9 filed on Dec. 15, 2022. The disclosure of these applications is incorporated herein by reference in its entirety as part of the present application.

### TECHNICAL FIELD

The present disclosure relates to an optical ranging device, and more particularly, to an optical ranging device based on Direct Time of Flight (DToF).

### BACKGROUND

A DToF-based optical ranging method is a ranging method that measures a distance between a ranging device and an object to be measured according to time of flight of light between the ranging device and the object to be measured. In a general DToF ranging method, the light source of the ranging device emits a pulsed measurement light to the object to be measured, and the measurement light is reflected back to the ranging device after shining on the object to be measured. A Single Photon Avalanche Diode (SPAD) of the ranging device receives the reflected light and generates electrical pulses, and the ranging device counts the electrical pulses to obtain a distribution of count values corresponding to a distribution of the reflected light intensity. Based on the distribution of the count values, the reception time at which the reflected light pulse is received can be determined, and the time difference between the reception time of the reflected light pulse and the emission of the corresponding measurement light pulse is the time of flight of the light, so that the distance between the object to be measured and the ranging device can be calculated based on the time of flight and the speed of light. The DToF ranging method uses the SPAD to directly measure the time of flight of laser.

However, in the DToF ranging method, if the object to be measured is too close, the intensity of the reflected measurement light is too strong, and the pile up effect tends to occur, which will lead to distortion of the DToF ranging results.

### SUMMARY

The present disclosure provides an optical ranging device that reduces or eliminates the pile up effect of the DToF ranging.

According to an aspect of the present disclosure, there is provided an optical ranging device, comprising: a light source for emitting pulsed measurement light; a sensor module comprising a Single Photon Avalanche Diode (SPAD) array for receiving measurement light reflected from an object to be measured, wherein the SPAD array comprises a first SPAD group with at least one SPAD and a second SPAD group with at least one SPAD, no aperture is arranged on the first SPAD group, and a first aperture for reducing light-passing amount is arranged on each SPAD of the second SPAD group, the sensor module separately outputs a photon detection value corresponding to a number of photons received by each SPAD group based on the measurement light received by every SPAD; and a processing module for calculating a distance between the object to be measured and the ranging device using the photon detection value based on Direct Time of Flight (DToF), wherein, in response to light intensity received by the SPAD array in a first pulse window being greater than a first threshold, the processing module calculates the distance using the photon detection value of the second SPAD group in the first pulse window but not using the photon detection value of the first SPAD group in the first pulse window.

In some embodiments, the optical ranging device further comprises: a storage module for separately storing the photon detection value of each SPAD group, wherein the processing module calculates the distance using the photon detection values stored in the storage module.

In some embodiments, the SPAD array further comprises a third SPAD group with at least one SPAD, on each SPAD of which a second aperture for reducing light-passing amount is arranged, and the light-passing amount of the second aperture is greater than the light-passing amount of the first aperture; and in response to the light intensity received by the SPAD array in the first pulse window being less than the first threshold but greater than a second threshold, the processing module calculates the distance using the photon detection value of the third SPAD group in the first pulse window or using the photon detection values of the third SPAD group and the second SPAD group in the first pulse window but not using the photon detection value of the first SPAD group in the first pulse window, and the second threshold is less than the first threshold.

In some embodiments, in response to the light intensity received by the SPAD array in the first pulse window being less than a third threshold, the processing module calculates the distance using the photon detection value of the first SPAD group in the first pulse window or using the photon detection values of all SPAD groups in the first pulse window, and the third threshold is the minimum threshold among the thresholds used by the processing module to determine the magnitude of the photon detection value.

In some embodiments, the light intensity received by the SPAD array in the first pulse window is represented by the photon detection value of the first SPAD group in the first pulse window.

In some embodiments, the second SPAD group and/or the third SPAD group each comprises a plurality of SPADs. Optionally, the plurality of SPADs of the second SPAD group and/or the third SPAD group are dispersedly distributed.

In some embodiments, outputting the photon detection value corresponding to the number of photons received by each SPAD group comprises outputting a total photon detection value corresponding to a total number of photons received by each SPAD group, or separately outputting a respective photon detection value corresponding to the number of photons received by each SPAD in each SPAD group.

In some embodiments, the first aperture and/or the second aperture is/are a metal aperture integrated in a chip of the SPAD array or is/are a metal aperture or a polymeric material aperture attached above a chip of the SPAD array.

In some embodiments, the processing module calculates the distance using a plurality of pulse windows.

In some embodiments, the processing module comprises a Micro Processing Unit (MCU).

According to another aspect of the present disclosure, there is provided an optical ranging device, comprising: a light source for emitting pulsed measurement light; a sensor module comprising a Single Photon Avalanche Diode (SPAD) array for receiving measurement light reflected from an object to be measured, wherein the SPAD array comprises a first SPAD group with at least one SPAD and a second SPAD group with at least one SPAD, no aperture is arranged on the first SPAD group, and a first aperture for reducing light-passing amount is arranged on each SPAD of the second SPAD group, and the sensor module separately outputs a photon detection value corresponding to a number of photons received by each SPAD group based on the measurement light received by every SPAD; and a processing module for calculating a distance between the object to be measured and the ranging device based on Direct Time of Flight (DToF) using the photon detection value, wherein, in response to light intensity received by the SPAD array in a first pulse window being less than a third threshold, the processing module calculates the distance using the photon detection value of the first SPAD group in the first pulse window or using the photon detection values of all SPAD groups in the first pulse window.

According to the embodiments of the present disclosure, not only the pile up effect in the DToF ranging method can be reduced or eliminated, but also the detection value of the SPAD array in each pulse window can be fully utilized to improve the real-time property and accuracy of ranging.

### BRIEF DESCRIPTION OF THE DRAWINGS

These and/or other aspects, features and advantages of the present disclosure will become clearer and easier to understand through the following description of the embodiments in conjunction with the accompanying drawings, among which:

FIG. 1 shows an exemplary distribution for photon count value with respect to time in the DToF ranging method;

FIG. 2 shows a structural block diagram of an optical ranging device according to an embodiment of the present disclosure;

FIG. 3 shows a schematic diagram of a SPAD array according to an embodiment of the present disclosure;

FIGS. 4A and 4B show schematic diagrams of a SPAD array according to another embodiment of the present disclosure, respectively;

FIG. 5 shows a schematic diagram of a SPAD array according to a further embodiment of the present disclosure.

### DETAILED DESCRIPTION OF THE EMBODIMENTS

The present disclosure will be described in detail below with reference to exemplary embodiments of the present disclosure. However, the present disclosure is not limited to the embodiments described herein, and it may be implemented in many different forms. The described embodiments are only used to make the present disclosure thorough and complete, and to fully convey the concept of the present disclosure to those skilled in the art. The features of the various described embodiments may be combined or replaced with each other, unless explicitly excluded or should be excluded according to the context.

As illustrated in the background, the DToF ranging method is prone to pile up effect for objects to be measured that are too close. The principle of the pile up effect is that, before the electrical pulse generated by a previous photon received by the SPAD is eliminated, another photon arrives, resulting in a mixture of electrical pulses generated by two or more photons, thus making the number of photons of the intense light cannot be accurately counted. The pile up effect can be reflected as a shift in the center of gravity of the distribution for the photon count values of the measured pulse light in ranging. When the center of gravity of the distribution for the photon count values shifts, the time of flight of the light determined therefrom is distorted, resulting in inaccurate ranging. The distribution for the measured photon count values can be represented as a histogram, and the shift in the center of gravity of the distribution for the photon count values can be reflected as a shift in the center of gravity of the histogram.

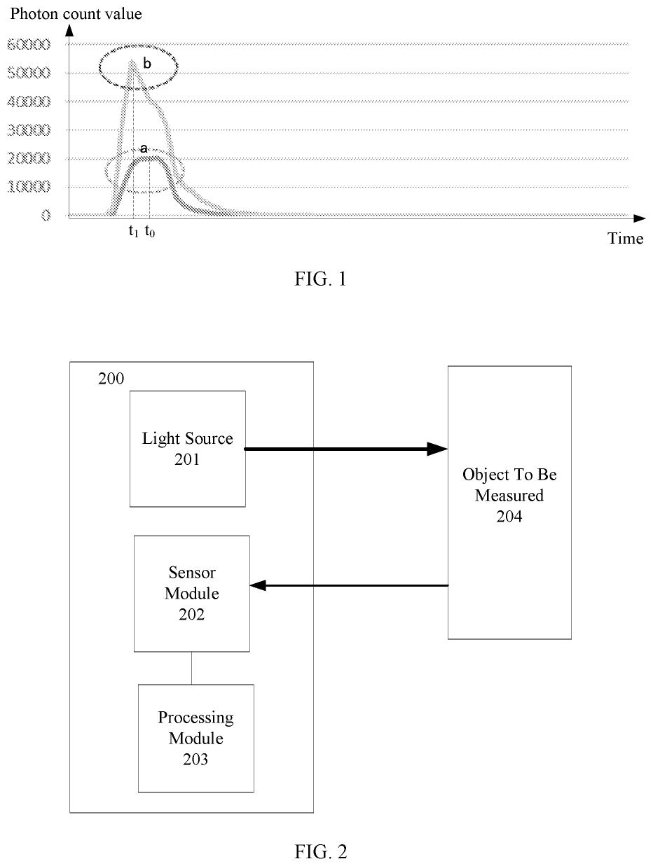

The pile up effect of the DToF ranging method and its influence on the measurement results are illustrated exemplarily below with reference to FIG. 1. FIG. 1 shows an exemplary distribution for photon count values of the DToF ranging method with respect to time. In FIG. 1, the vertical axis is the photon count value, and the horizontal axis is the time of generation of the photon count value. FIG. 1 shows two distributions a and b for the photon count values, and the emitted measurement light corresponding to these two distributions for the photon count values is an approximately bilaterally symmetrical pulse light. The lower curve of FIG. 1 is distribution a for the photon count value without the pile up effect, and distribution a for the photon count value appears as approximately symmetrical pulse, which is approximately consistent with the pulse shape of the emitted measurement light. The center of gravity of distribution a for the photon count value is approximately located at time point to at the center of the pulse. The upper curve of FIG. 1 is distribution b for the photon count value with pile up effect, and distribution b for photon count values is an asymmetric pulse, which has a large deviation from the pulse shape of the emitted measurement light. In the pulse of distribution b for the photon count value, the maximum value of the count values appears at time point ti on the left side of the pulse, resulting in the center of gravity of the pulse shift to the left. The reason for this phenomenon is that the intensity of the pulse light reflected from the close object to be measured is high, and the pile up effect occurs after time point ti, so that not all photons can be counted, resulting in decrease of the counted number of photons. In the case of the center of gravity of the distribution of photon count values shifts due to the pile up effect, a deviation in the time of flight of the light determined based on the center of gravity of the distribution for the photon count value occurs, and thus a deviation in the calculated distance of the object to be measured also occurs. For example, in distribution b of photon count values in FIG. 1, the center of gravity of the pulse may be determined as time point ti, while the actual center of gravity of the pulse should be time point to, so that the measurement distance determined from time point ti will be less than the time point determined based on time point to, that is, smaller than the actual distance of the object to be measured.

The present disclosure aims to reduce or eliminate the pile up effect of the DToF ranging method and the resulting measurement error. To this end, the embodiments of the present disclosure propose an optical ranging device that reduces light-passing amount of the SPADs with apertures. In the optical ranging device of embodiments of the present disclosure, the apertures are arranged above part of the SPADs in the sensor to reduce the light-passing amount of the corresponding SPADs, and the processing module can determine the measurement distance by selecting the detection results of different SPADs according to different light intensities. For example, for large light intensity, the measurement distance is determined by the detection result of the SPAD with aperture, so that the pile up effect of large light intensity can be avoided. For small light intensity, the detection results of SPADs without aperture can be used to ensure the accuracy of the measurement and large measurement distance. Furthermore, in the embodiments of the present disclosure, all SPADs in the sensor (whether or not provided with the aperture) can detect the measurement light at the same time, so that the processing module can obtain the detection results of all SPADs in the same time period. Then, the processing module can determine the light intensity in any time period according to predetermined rules and determine the measurement distance in the time period using the detection results of appropriate SPAD in the time period according to the light intensity in the time period. In the DToF ranging method, the measurement light is emitted in the form of pulse, so that the light received by the sensor is also pulsed light. The time period during which the sensor receives a light pulse may be referred to as a pulse window. According to embodiments of the present disclosure, since all SPADs in the sensor can detect the measurement light at the same time, the processing module can perform the light intensity determination and ranging based on the detection value of the same pulse window, without first determining the light intensity according to the detection value of the previous pulse window and then performing ranging in the subsequent pulse window according to the determination result. For example, if the SPADs in the sensor cannot detect the measurement light at the same time, but some SPADs are enabled to detect according to the light intensity, then only the first SPAD group (without aperture) will be enabled when the light intensity is not too large, and the second SPAD group (with aperture) will be enabled to detect only when the first SPAD group detects that the light intensity is too large in a certain pulse window (the first pulse window). Therefore, the second SPAD group has no detection value in the first pulse window and cannot perform ranging based on the detection value in the first pulse window. In this case, ranging can be performed using the detection value of the second SPAD group only in the subsequent pulse window after the second SPAD group is enabled, i.e., light intensity determination and ranging cannot be performed based on the detection value in the same pulse window. On the contrary, the optical ranging device according to embodiments of the present disclosure can perform light intensity determination and ranging using the detection values of the same pulse window without wasting the pulse window for light intensity determination, so that the detection value of each pulse window can be more fully utilized. Moreover, since the detection value of the same pulse window is used for light intensity determination and ranging, the detection value used for ranging has no lag relative to the light intensity determination result, and there is no distortion in ranging caused by the expiration of the light intensity determination result. Therefore, the optical ranging device according to embodiments of the present disclosure is not only able to reduce or eliminate the pile up effect, but also to further improve the real-time property and accuracy of ranging.

FIG. 2 shows a structural block diagram of an optical ranging device 200 according to an embodiment of the present disclosure. The optical ranging device 200 includes a light source 201, a sensor module 202 and a processing module 203.

The light source 201 is used to emit pulsed measurement light to, for example, an object to be measured 204. The light source 201 may be any light source suitable for optical ranging, for example, it may be a semiconductor laser, such as a vertical cavity surface emitting laser (VCSEL). The light source 201 may emit pulsed measurement light by means of pulse modulation.

The sensor module 202 is used to receive the measurement light reflected from the object to be measured 204 and to generate a detection value corresponding to the measurement light for measuring the distance of the object to be measured 204. Specifically, the sensor module 202 includes a SPAD array for receiving the measurement light reflected from the object to be measured 204. The SPAD array may include a plurality of SPADs arranged in rows and columns. After receiving the measurement light, the SPADs will convert the received photons into electrical pulses. Generally, the SPADs may convert each photon received into an electrical pulse. The sensor module 202 may obtain a photon detection value corresponding to the number of photons by, for example, counting the electrical pulses output by the SPADs via a counter. The photon detection value may be, for example, the count value of the electrical pulses, or other metrics that can indicate the number of photons, such as the interval time between the electrical pulses. The number of photons within a fixed time can indicate the light intensity at that time.

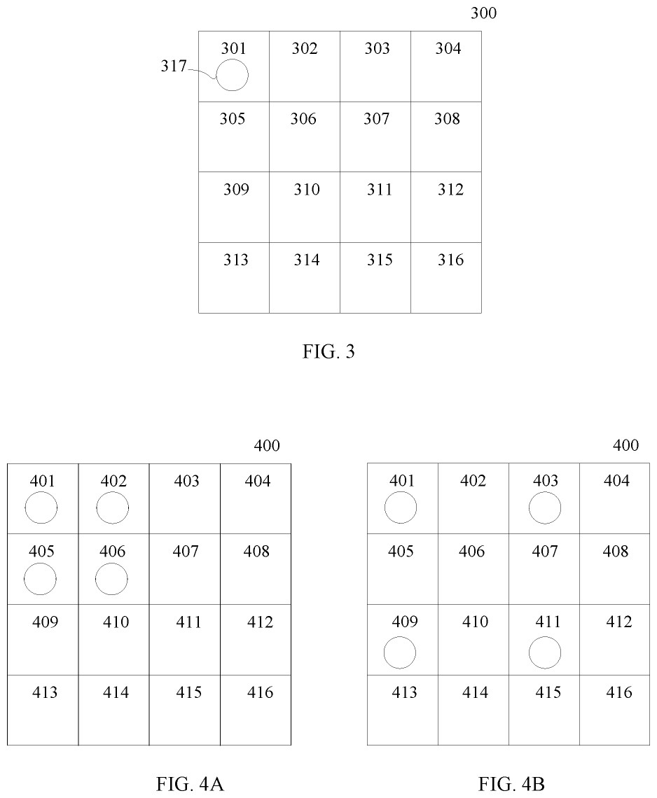

According to an embodiment of the present disclosure, the SPAD array may include a plurality of SPAD groups, including, for example, a first SPAD group with at least one SPAD and a second SPAD group with at least one SPAD, where no aperture is arranged on the first SPAD group, and a first aperture for reducing the light-passing amount is arranged on each SPAD of the second SPAD group. FIG. 3 shows a schematic diagram of a SPAD array 300 according to an embodiment of the present disclosure. As shown in FIG. 3, the SPAD array 300 is a 4×4 array, which is shown only as an example, and those skilled in the art may choose other suitable array sizes according to the actual application requirements under the concept of the present disclosure.

In FIG. 3, the SPAD array 300 includes 16 SPADs 301-316 for respectively receiving the measurement light reflected from the object to be measured. The SPADs 301-316 include two groups, the first group includes SPADs 302-316, and the second group includes SPAD 301. The difference between the first SPAD group and the second SPAD group is whether the SPAD is provided with the aperture for reducing the light-passing amount. None of the SPADs 302-316 of the first group is provided with the aperture, while the SPAD 301 of the second group is provided with an aperture 317 for reducing the light-passing amount. The purpose of providing the second SPAD group in the SPAD array is to reduce the number of photons received by the SPADs (i.e., reduce the light-passing amount) in the case where the reflected light is too strong (e.g., the object to be measured is too close), so as to reduce or eliminate the pile up effect. The aperture can be of any form or shape as long as it can reduce the light-passing amount. For example, it can be a light shield with a circular aperture as shown in FIG. 3, and the light shield can be a metal material or other suitable materials, such as polymer materials.

It should be noted that both the first SPAD group and the second SPAD group may each include one or more SPADs. In the example of FIG. 3, the first SPAD group includes a plurality of SPADs, and the second SPAD group includes one SPAD. Obviously, the second SPAD group may also include a plurality of SPADs, and the first SPAD group may also include one SPAD.

FIGS. 4A and 4B show schematic diagrams of a SPAD array 400 according to another embodiment of the present disclosure. In the SPAD array 400 shown in FIGS. 4A and 4B, the second SPAD group includes 4 SPADs. The second SPAD group in FIG. 4A includes SPADs 401, 402, 405 and 406, each of which is provided with an aperture for reducing the light-passing amount; the first SPAD group includes the remaining SPADs, on which there is no aperture. The second SPAD group in FIG. 4B includes SPADs 401, 403, 409 and 411, each of which is also provided with one aperture for reducing the light-passing amount; the first SPAD group includes the remaining SPADs, on which there is no aperture. When a plurality of SPADs in the SPAD array are provided with apertures, the measurement accuracy can be improved when the detection results of the second SPAD group are used for distance measurement. For example, a certain SPAD may not receive the reflected light correctly due to reflection angle or occlusion, etc. In this case, if the second group has multiple SPADs, the distance measurement can still be performed by the detection results of other SPADs. The difference between FIG. 4A and FIG. 4B is whether the SPADs of the second group are dispersedly distributed or not. The SPADs of the second group in FIG. 4A are closely distributed, but the SPADs of the second group in FIG. 4B are dispersedly distributed. In the case of dispersedly distributed, the measurement accuracy can be further improved. The reason is that the SPADs that cannot receive reflected light correctly due to reflection angle or occlusion, etc. tend to be concentrated together, and the use of dispersedly distributed SPADs can try to avoid that none of the SPADs in the second group can receive the reflected light correctly.

Returning to FIG. 2, the sensor module 202 may separately output a photon detection value corresponding to the number of photons received by each SPAD group based on the measurement light received by every SPAD in the SPAD array. According to embodiments of the present disclosure, every SPAD in the SPAD array receives measurement light and outputs electrical pulses, without disabling some SPADs according to different light intensities. Therefore, the sensor module 202 may output the photon detection value corresponding to the number of photons received by each SPAD group based on the sensing of the measurement light and the output electrical pulses by every SPAD. In other words, the sensor module 202 can measure each SPAD group and output the photon detection value corresponding to the number of photons received by each group. The photon detection value output by the sensor module 202 include photon detection values at multiple times, that is, it is a distribution of detection values over time, representing a distribution of the number of photons received by the SPADs over time. According to embodiments of the present disclosure, the sensor module 202 may output a photon detection value corresponding to the number of photons received by each SPAD group as follows. In one embodiment, a total photon detection value corresponding to the total number of photons received by each SPAD group may be output. In another embodiment, a respective photon detection value corresponding to the respective number of photons received by each SPAD in each SPAD group may be output separately. For example, the sensor module 202 may count the electrical pulses output by each SPAD in each group separately, and output the photon detection value corresponding to each SPAD in each group separately. Alternatively, the sensor module 202 may count the electrical pulses output by each SPAD in each group respectively, but output the total photon detection value or the average photon detection value for all SPADs in each group for each group of SPAD. Alternatively, the sensor module 202 may count the electrical pulses output by all SPADs in each group together and output the total photon detection value or the average photon detection value for all SPADs in each group for each SPAD group.

The processing module 203 is used to calculate the distance between the object to be measured 204 and the ranging device 200 based on the principle of DToF ranging using the photon detection values output by the sensor module 202. The principle of DToF ranging is to calculate the distance between the object to be measured and the ranging device according to the time difference between the time the sensor receives the reflected light pulse and the time of emission of the measured light pulse (i.e., the time of flight). The processing module 203 can determine the time at which the sensor module 202 receives the reflected light pulse according to the photon detection values output by the sensor module 202, for example, determine the reception time based on the center of gravity of the distribution for photon detection values.

As stated above, when the object to be measured 204 is too close, the reflected light is too strong, and the pile up effect may occur. To solve or mitigate this problem, according to embodiments of the present disclosure, when the received reflected light is too strong, only the photon detection value of the SPAD with an aperture is used to determine the measurement distance. Since the aperture can reduce the number of photons incident on the SPADs, the number of photons actually detected on the SPADs will be reduced, which can reduce or eliminate the pile up effect and improve the measurement accuracy. According to embodiments of the present disclosure, in response to the light intensity received by the SPAD array in the first pulse window being greater than a first threshold, the processing module 203 calculates the distance using the photon detection values of the second SPAD group in the first pulse window but not using the photon detection values of the first SPAD group in the first pulse window.

To determine whether the intensity of the reflected light is too strong and thus causes the pile up effect, a determination threshold (e.g., a first threshold) can be set for comparison. When the light intensity of the reflected light received by the SPAD array is greater than the first threshold, it can be determined that the photon detection value of the SPAD with aperture is required for distance measurement. However, the light intensity of the reflected light varies with time, and thus the determination of the light intensity also needs to be made according to time. According to embodiments of the present disclosure, the light intensity is determined in terms of the pulse window, that is, the light intensity is determined in terms of the time period during which one light pulse is received. For example, the processing module 203 may compare the light intensity received by the SPAD array in the first pulse window with the first threshold to determine whether the light intensity in the time period of the first pulse window is too strong. When the light intensity received by the SPAD array in the first pulse window is greater than the first threshold, the processing module 203 calculates the distance using the photon detection values of the second SPAD group (i.e., SPADs with the first aperture) in the first pulse window but not using the photon detection values of the first SPAD group (i.e., SPADs without the first aperture) in the first pulse window. Therefore, according to embodiments of the present disclosure, in the case where it is determined that the light intensity in a certain pulse window is too strong, the distance can be calculated using the photon detection values of the SPADs with apertures in the same pulse window. In this way, not only can the pile up effect be reduced or eliminated, and the measurement accuracy be improved, but also the distance measurement can be performed by making full use of each pulse window to improve the real-time property and accuracy of distance measurement. In the present disclosure, both the first SPAD group and the second SPAD group in the SPAD array receive reflected light without disabling a certain SPAD group (e.g., disabling the second SPAD group). Therefore, in the case where it is determined that the intensity of the reflected light in a certain pulse window is too strong, the photon detection value of the second SPAD group in the same pulse window can be directly used to measure the distance without switching the SPADs receiving reflected light to the second SPAD group in the subsequent pulse windows in order to obtain the photon detection values of the second SPAD group.

According to embodiments of the present disclosure, in order for the processing module 203 to better utilize the photon detection values in the same pulse window for light intensity determination and distance measurement, the optical ranging device 200 may further include a storage module for storing the photon detection value of each SPAD group separately, so that the processing module 203 may calculate the distance using the photon detection values stored in the storage module.

It should be noted that, in embodiments of the present disclosure, calculating the distance using the photon detection value of the SPAD in the first pulse window does not mean that only the photon detection value in one pulse window is used to calculate the distance, but only means that the pulse window for determining the light intensity and the pulse window for detecting the photon detection values are the same pulse window. In embodiments of the present disclosure, the processing module may calculate the distance using a plurality of pulse windows, for example, the distance may be calculated by the average of the photon detection values of the plurality of pulse windows, or the distance may be calculated first with the photon detection value of each pulse window separately, and then the distances calculated in the plurality of pulse windows are averaged.

According to embodiments of the present disclosure, the first threshold value described above may be predetermined based on experiments or experiences. The light intensity received by the SPAD array in the first pulse window may be represented in a variety of ways, for example, it may be represented by the photon detection values of one or more SPADs in the SPAD array in the first pulse window. In one embodiment, the light intensity received by the SPAD array in the first pulse window may be represented by the photon detection value of the first SPAD group in the first pulse window. For example, the light intensity is represented according to the maximum, average or sum of the photon detection values of the first SPAD group in the first pulse window. In another embodiment, the light intensity received by the SPAD array in the first pulse window may be represented by the photon detection values of all SPADs of the SPADs in the first pulse window. For example, the light intensity is represented according to the maximum, average or sum of the photon detection values of all SPADs in the first pulse window over the time period.

According to the above embodiments of the present disclosure, not only can the pile up effect be reduced or eliminated, but also the detection value of each pulse window can be fully utilized to improve the real-time property and accuracy of ranging.

Further, the SPAD array according to embodiments of the present disclosure can include more SPAD groups in addition to the first SPAD group and the second SPAD group, and different SPAD groups can be provided with apertures with different light-passing amounts, so that the photon detection values of different SPAD groups can be used for different light intensity levels to measure the distance, further improving the measurement accuracy and measurement range.

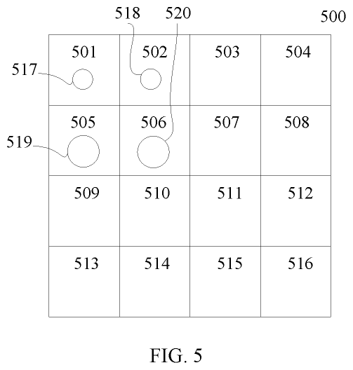

For example, the SPAD array may further comprise a third SPAD group with at least one SPAD, on each SPAD of which a second aperture for reducing light-passing amount is arranged, and the light-passing amount of the second aperture is greater than that of the first aperture. Like the second SPAD group, the third SPAD group may comprise one or more SPADs, and a plurality of SPADs in the third SPAD group may also be distributed dispersedly or closely. For example, FIG. 5 shows a schematic diagram of a SPAD array 500 according to another embodiment of the present disclosure. In the example of FIG. 5, the SPAD array 500 includes three SPAD groups. The first SPAD group includes SPADs 503, 504, 507-516, on which no aperture is arranged; the second SPAD group includes SPADs 501, 502, on which first apertures 517, 518 are arranged; the third SPAD group includes SPADs 505, 506, on which second apertures 519, 520 are arranged, respectively. The light-passing amount of the second apertures 519, 520 is greater than that of the first apertures 517, 518.

In the embodiment where the SPAD array further includes the third SPAD group, the light intensity received by the SPAD array can be compared to a second threshold in addition to the first threshold, and the second threshold is less than the first threshold, so that the light intensity can be classified into three levels. If the light intensity received by the SPAD array in the first pulse window is greater than the first threshold, the processing module calculates the distance using the photon detection value of the second SPAD group in the first pulse window. If the light intensity received by the SPAD array in the first pulse window is less than the first threshold but greater than the second threshold, the processing module calculates the distance using the photon detection value of the third SPAD group in the first pulse window or using the photon detection values of the third SPAD group and the second SPAD group in the first pulse window. In the case where the light intensity is greater than the first threshold, the light intensity is the strongest, so the distance is calculated using the detection value of the second SPAD group arranged with the first aperture with the smallest light-passing amount. In the case where the light intensity is less than the first threshold but greater than the second threshold, the light intensity is medium, and the distance can be calculated using the detection values of the third SPAD group arranged with the second aperture with greater light-passing amount. In this way, the pile up effect can be reduced or avoided, the measurement accuracy can be improved, and the measurement range can be expanded. Alternatively, in the case where the light intensity is less than the first threshold but greater than the second threshold, the distance can be calculated using the detection values of both the third SPAD group and the second SPAD group at the same time, as long as the detection values of the first SPAD group are not used. In this case, the pile up effect can still be reduced or avoided since both the second SPAD group and the third SPAD group have apertures.

Obviously, according to embodiments of the present disclosure, the SPAD array can also include more SPAD groups, and the light intensity can be classified into more levels. Thus, not only the pile up effect can be reduced or avoided, but also the measurement accuracy can be further improved and the measurement range can be expanded.

Furthermore, in the case where the SPAD array according to an embodiment of the present disclosure includes the first SPAD group and one or more other SPAD groups arranged with apertures, the processing module may calculate the distance by using the photon detection value of the first SPAD group in the first pulse window or by using the photon detection values of all SPAD groups in the first pulse window in response to the light intensity received by the SPAD array in the first pulse window being less than the third threshold. The third threshold is a threshold used to determine whether the light intensity is at the minimum level. When the light intensity is less than the third threshold, there is no pile up effect even for the photon detection value of the SPADs without aperture (i.e., the first SPAD group). Therefore, the distance can be calculated by using the photon detection value of the first SPAD group or the photon detection values of all SPADs. The third threshold may be the smallest threshold among the thresholds used by the processing module to determine the magnitude of the photon detection values. For example, in the above case where there are only two SPAD groups and one threshold, the third threshold may be the same as the first threshold; in the above case where there are three SPAD groups and two thresholds, the third threshold may be the same as the second threshold. If the SPAD array has more SPAD groups and there are more thresholds, the third threshold is the smallest one.

In embodiments of the present disclosure, the aperture may be any form of aperture, and may be arranged above the SPAD in various suitable ways. For example, the aperture may be a metal aperture integrated in the chip of the SPAD array, so that the metal aperture may be manufactured using a unified process for manufacturing the SPAD array, thereby reducing manufacturing cost and improving the integration of the sensor module. Further, for example, the aperture may be a metal aperture, or a polymeric material aperture attached to the chip of SPAD array. In this example, the aperture can be attached to a conventional SPAD array chip that has been manufactured, thus the process flow of the existing SPAD array may not be changed, and the cost of modifying the existing process can be avoided.

The whole or parts of various units (e.g., processing module) described in the present disclosure may be implemented in suitable hardware, software, or hardware in combination with software, for example, in dedicated circuitry, firmware, software, or any combination thereof. For example, some aspects may be implemented in hardware, while other aspects may be implemented in firmware or software that can be executed by a controller, microprocessor, or other computing device. For example, the processing module in the present disclosure may comprise a microprocessor unit (MCU), and the MCU may be operated with software. The memory module of the present disclosure may be any suitable memory or storage area, which may be a stand-alone unit or integrated in other units, such as in a processing module.

The block diagrams of circuits, devices, apparatus, equipment, and systems involved in this disclosure are only exemplary examples and are not intended to require or imply that they must be connected, arranged, and configured in the manner shown in the block diagrams. As will be recognized by those skilled in the art, these circuits, devices, apparatus, equipment, and systems may be connected, arranged, and configured in any manner, as long as the desired purpose can be achieved.

It should be understood by those skilled in the art that the above-mentioned specific embodiments are only examples and not limitations, and various modifications, combinations, partial combinations and substitutions can be made to the embodiments of the present disclosure according to design requirements and other factors, so long as they are within the scope of the appended claims or their equivalents, that is, they belong to the scope of rights to be protected by the present disclosure.

What is claimed is:

1. An optical ranging device, comprising:
a light source for emitting pulsed measurement light;
a sensor module comprising a Single Photon Avalanche Diode (SPAD) array for receiving measurement light reflected from an object to be measured, wherein the SPAD array comprises a first SPAD group with at least one SPAD and a second SPAD group with at least one SPAD, no aperture is arranged on the first SPAD group, and a first aperture for reducing light-passing amount is arranged on each SPAD of the second SPAD group, the sensor module separately outputs a photon detection value corresponding to a number of photons received by each SPAD group based on the measurement light received by every SPAD; and
a processing module for calculating a distance between the object to be measured and the ranging device using the photon detection value based on Direct Time of Flight (DToF), wherein, in response to light intensity received by the SPAD array in a first pulse window being greater than a first threshold, the processing module calculates the distance using the photon detection value of the second SPAD group in the first pulse window but not using the photon detection value of the first SPAD group in the first pulse window.

2. The optical ranging device according to claim 1, further comprising:
a storage module for separately storing the photon detection value of each SPAD group,
wherein the processing module calculates the distance using the photon detection value stored in the storage module.

3. The optical ranging device according to claim 1, wherein,
the SPAD array further comprises a third SPAD group with at least one SPAD, on each SPAD of which a second aperture for reducing light-passing amount is arranged, and the light-passing amount of the second aperture is greater than the light-passing amount of the first aperture; and
in response to the light intensity received by the SPAD array in the first pulse window being less than the first threshold but greater than a second threshold, the processing module calculates the distance using the photon detection value of the third SPAD group in the first pulse window or using the photon detection values of the third SPAD group and the second SPAD group in the first pulse window but not using the photon detection value of the first SPAD group in the first pulse window, and the second threshold is less than the first threshold.

4. The optical ranging device according to claim 1, wherein,
in response to the light intensity received by the SPAD array in the first pulse window being less than a third threshold, the processing module calculates the distance using the photon detection value of the first SPAD group in the first pulse window or using the photon detection values of all SPAD groups in the first pulse window, and the third threshold is the minimum threshold among the thresholds used by the processing module to determine a magnitude of the photon detection value.

5. The optical ranging device according to claim 1, wherein,
the light intensity received by the SPAD array in the first pulse window is represented by the photon detection value of the first SPAD group in the first pulse window.

6. The optical ranging device according to claim 1, wherein,
the second SPAD group comprises a plurality of SPADs.

7. The optical ranging device according to claim 6, wherein,
the plurality of SPADs of the second SPAD group are dispersedly distributed.

8. The optical ranging device according to claim 3, wherein,
the second SPAD group and/or the third SPAD group each comprises a plurality of SPADs.

9. The optical ranging device according to claim 8, wherein,
the plurality of SPADs of the second SPAD group and/or the third SPAD group are dispersedly distributed.

10. The optical ranging device according to claim 1, wherein, outputting the photon detection value corresponding to the number of photons received by each SPAD group comprises:
outputting a total photon detection value corresponding to a total number of photons received by each SPAD group, or
separately outputting a respective photon detection value corresponding to the number of photons received by each SPAD in each SPAD group.

11. The optical ranging device according to claim 1, wherein,
the first aperture is a metal aperture integrated in a chip of the SPAD array or is a metal aperture or a polymeric material aperture attached above a chip of the SPAD array.

12. The optical ranging device according to claim 3, wherein,
the first aperture and/or the second aperture is a metal aperture integrated in a chip of the SPAD array or is a metal aperture or a polymeric material aperture attached above a chip of the SPAD array.

13. The optical ranging device according to claim 1, wherein,
the processing module calculates the distance using a plurality of pulse windows.

14. The optical ranging device according to claim 1, wherein,
the processing module comprises a Micro Processing Unit (MCU).

15. An optical ranging device, comprising:
a light source for emitting pulsed measurement light;
a sensor module comprising a Single Photon Avalanche Diode (SPAD) array for receiving measurement light reflected from an object to be measured, wherein the SPAD array comprises a first SPAD group with at least one SPAD and a second SPAD group with at least one SPAD, no aperture is arranged on the first SPAD group, and a first aperture for reducing light-passing amount is arranged on each SPAD of the second SPAD group, and the sensor module separately outputs a photon detection value corresponding to a number of photons received by each SPAD group based on the measurement light received by every SPAD; and
a processing module for calculating a distance between the object to be measured and the ranging device based on Direct Time of Flight (DToF) using the photon detection value, wherein, in response to light intensity received by the SPAD array in a first pulse window being less than a third threshold, the processing module calculates the distance using the photon detection value of the first SPAD group in the first pulse window or using the photon detection values of all SPAD groups in the first pulse window.
